(19) United States
(12) Patent Application Publication
(10) Pub. No.: US 2012/0217576 A1
(43) Pub. Date: Aug. 30, 2012

(54) SEMICONDUCTOR DEVICE AND METHOD FOR FORMING THE SAME

(75) Inventor: Tae Yeon YEO, Seoul (KR)

(73) Assignee: Hynix Semiconductor Inc., Icheon-si (KR)

(21) Appl. No.: 13/240,919

(22) Filed: Sep. 22, 2011

(30) Foreign Application Priority Data
Feb. 28, 2011 (KR) 10-2011-0017802

(51) Int. Cl. H01L 29/78

(52) U.S. Cl. 257/330; 257/770; 257/E29.262

(57) ABSTRACT

A semiconductor device and a method for forming the same are disclosed. According to the semiconductor device and the method for forming the same, a contact hole spacer is formed only over a contact hole sidewall such that a lower part of a contact plug is formed to have large critical dimension and therefore contact resistance is increased, and an upper spacer is not lost in a process of forming a contact hole sidewall spacer so as to prevent a Self Align Contact (SAC) failure from occurring. The semiconductor device includes a contact hole formed over a semiconductor substrate, a first conductive layer formed at a bottom region of the contact hole and a lower part of sidewalls of the contact hole, a spacer formed over the sidewalls of the contact hole, and a second conductive layer buried in the contact hole including the first conductive layer and the spacer.

### CROSS-REFERENCE TO RELATED APPLICATION

The priority of Korean patent application No. 10-2011-0017802 filed on 28 Feb. 2011, the disclosure of which is hereby incorporated in its entirety by reference, is claimed.

### BACKGROUND OF THE INVENTION

Embodiments of the present invention relate to a semiconductor device and a method for forming the same, and more particularly to a semiconductor device including a buried gate and a method for forming the same.

It is necessary to increase the number of semiconductor memory chips that can be formed on a wafer of a given size in order to increase its productivity. A variety of methods have been proposed to reduce a unit area of a semiconductor memory device. One such method employs a recess gate wherein a recess is formed in a substrate and a gate is formed in the recess such that a channel region is formed in a curved shape along the recess, instead of using a conventional planar gate having a horizontal channel region. Another proposed method wholly buries a gate in a recess to form a buried gate.

In the case of the buried gate, a gate is wholly buried in the semiconductor substrate, so that a channel length and width can be elongated, and parasitic capacitance between a gate (word line) and a bit line can be decreased by about 50% as compared to a conventional planar gate.

However, under this configuration, a space (height) in a cell region remains as high as a gate in the peripheral region. Accordingly, a method is necessary for utilizing a difference in the space (height). Some methods have been used in the related art. For example, the related art has proposed a method of forming a cell region space as high as a gate in a peripheral region. And another method of forming a bit line in a cell region and a gate in a peripheral area simultaneously is proposed (GBL).

### BRIEF SUMMARY OF THE INVENTION

Various embodiments of the present invention are directed to providing a semiconductor device and a method for forming the same that substantially obviate one or more problems due to limitations and disadvantages of the related art.

An embodiment of the present invention relates to a semiconductor device, and a method for forming the same, in which a contact hole spacer is formed only over a contact hole sidewall in such a manner that a lower part of a contact plug is formed to have a large critical dimension, thus increasing contact resistance, and an upper spacer is not lost in the process of forming a contact hole sidewall spacer so as to prevent a Self Align Contact (SAC) failure from occurring.

In accordance with an aspect of the present invention, a semiconductor device includes a contact hole formed over a semiconductor substrate, a first conductive layer formed at a bottom region of the contact hole and a lower part of sidewalls of the contact hole; a spacer formed over the sidewalls of the contact hole, and a second conductive layer buried in the contact hole including the first conductive layer and the spacer. According to the semiconductor device, a contact hole spacer is formed only over a contact hole sidewall in such a manner that a lower part of a contact plug is formed to have large critical dimension, thus increasing contact resistance, and an upper spacer is not lost in a process of forming a contact hole sidewall spacer so as to prevent SAC failure from occurring.

The first conductive layer may be configured in a form of ‘U’ or ‘U’ lying on a side.

The first conductive layer formed at the bottom region of sidewalls of the contact hole has a specific critical dimension, wherein the specific critical dimension of the first conductive layer is 0.9 to 1.1 times a critical dimension of the spacer formed over the sidewalls of the contact hole.

The first conductive layer may include polysilicon. The spacer may include a nitride film, and the second conductive layer includes at least one of titanium (Ti), titanium nitride (TiN), or tungsten (W).

The semiconductor device may further include a bit line formed over the second conductive layer. The second conductive layer may be contained in a bit line. The first conductive layer may be formed to have a thickness of 400 nm to 500 nm

The semiconductor substrate may include a cell region and a peripheral region, and may also include a buried gate buried in a substrate of the cell region and a peripheral circuit gate formed over a substrate of the peripheral region.

The peripheral circuit gate may have the same height as that of a bit line of the cell region.

The peripheral circuit gate may include a polysilicon layer, a barrier metal layer, a tungsten (W) layer, and a hard mask layer. The bit line of the cell region may include a barrier metal layer, a tungsten (W) layer, and a hard mask layer.

In accordance with another aspect of the present invention, a method for forming a semiconductor device includes forming a contact hole over a semiconductor substrate; forming a first conductive layer at a bottom region of the contact hole and a lower part of sidewalls of the contact hole; forming a spacer over the sidewalls of the contact hole; and burying a second conductive layer in the contact hole including the first conductive layer and the spacer. According to a method for forming the semiconductor device, a contact hole spacer is formed only over a contact hole sidewall in such a manner that a lower part of a contact plug is formed to have large critical dimension, thus increasing contact resistance, and an upper spacer is not lost in a process of forming a contact hole sidewall spacer so as to prevent SAC failure from occurring.

The formation of the first conductive layer may include forming a first conductive layer at a bottom region and sidewalls of the contact hole, forming an insulation film over the first conductive layer, and etching some parts of the first conductive layer.

The insulation film may include at least one of SiO2, Boron Phosphorus Silicate Glass (BPSG), Phosphorus Silicate Glass (PSG), Tetra Ethyle Ortho Silicate (TEOS), Un-doped Silicate Glass (USG), Spin On Glass (SOG), High Density Plasma (HDP), Spin On Dielectric (SOD), Plasma enhanced Tetra Ethyle Ortho Silicate (PE-TEOS), and Silicon Rich Oxide (SROx).

The formation of the spacer may include depositing a spacer material in an empty space formed by the etched first conductive layer, and planarizing/etching the spacer material.

The first conductive layer may include polysilicon. The spacer may include a nitride film, and the second conductive layer may include at least one of titanium (Ti), titanium nitride (TiN) or tungsten (W).

The method may further include, prior to the formation of the contact hole, forming a device isolation film defining an active region in the semiconductor substrate, forming a recess in the semiconductor substrate; forming a buried gate at a lower part of the recess, and forming a capping film over the buried gate and the semiconductor substrate.

The contact hole may be formed by etching of the capping film. The first conductive layer may be configured in a form of ‘U’ or ‘U’ lying on a side.

The first conductive layer formed at the bottom region of sidewalls of the contact hole may have a specific critical dimension, wherein the specific critical dimension of the first conductive layer is 0.9 to 1.1 times a critical dimension of the spacer formed over the sidewalls of the contact hole.

The first conductive layer may be formed to have a thickness of 40 nm to 50 nm. The formation of the second conductive layer may be carried out and at the same time a gate conductive layer of a peripheral region is formed.

### BRIEF DESCRIPTION OF THE DRAWINGS

FIG. 1 is a plan view illustrating a semiconductor device according to an embodiment of the present invention.

FIGS. 2 to 14 sequentially show a method for forming a semiconductor device according to an embodiment of the present invention.

### DESCRIPTION OF EMBODIMENTS

Reference will now be made in detail to embodiments of the present invention, examples of which are illustrated in the accompanying drawings. Wherever possible, the same reference numbers will be used throughout the drawings to refer to the same or like parts. A semiconductor device and a method for forming the same according to embodiments of the present invention will hereinafter be described with reference to the appended drawings.

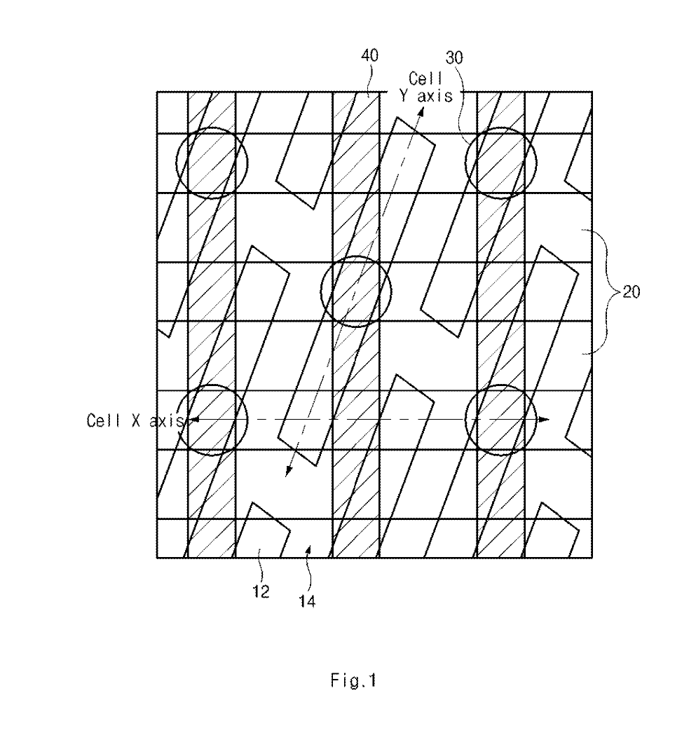

FIG. 1 is a plan view illustrating a semiconductor device according to an embodiment of the present invention. Specifically, FIG. 1 shows a cell region of a semiconductor device. Referring to FIG. 1, a semiconductor substrate includes an island-patterned active region 12 and a device isolation film 14 for defining the active region 12. Shallow Trench Isolation (STI) may be applied to form the device isolation film 14 by forming a trench in the semiconductor substrate. Then, an insulation film such as an oxide film is used to fill in the trench. Preferably, the active region 12 may be tilted at a predetermined angle with respect to a word line or a bit line so as to form a 6F2 layout (where F denotes a critical dimension, which is a minimum pattern size obtainable under a given process condition).

Bit lines 40 are formed, to pass across the active region 12, and extend along a first direction, as shown in FIG. 1. A bit line contact 30 is formed where the bit line 40 and the active region 12 overlap. In addition, word lines (i.e., gate) 20 in each active region 12 are configured to pass across the active region 12 and extend along a second direction perpendicular to the first direction.

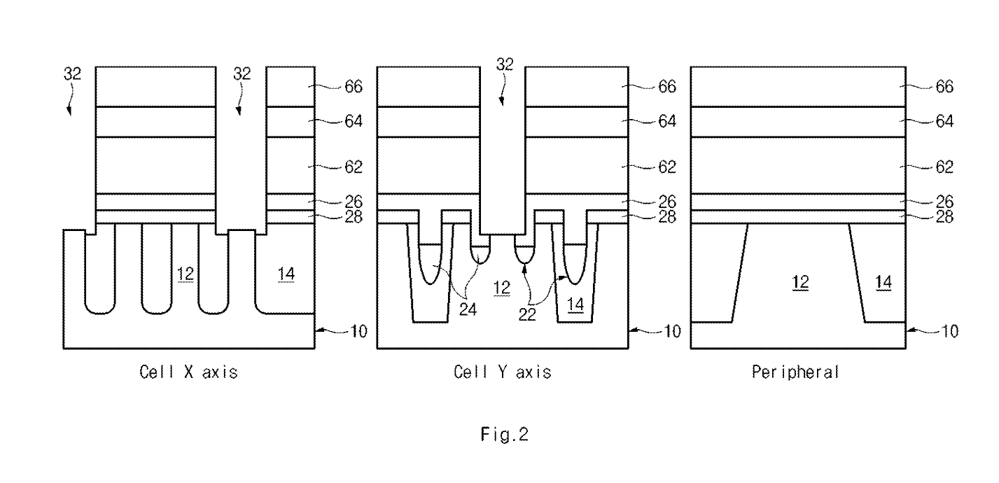

FIGS. 2 to 14 sequentially show a method for forming a semiconductor device according to an embodiment of the present invention. In more detail, FIGS. 2 to 14 sequentially show cross-sectional views illustrating the semiconductor of FIG. 1 device taken along the ‘Cell X axis’, cross-sectional views illustrating the semiconductor of FIG. 1 taken along the ‘Cell Y axis’, and cross-sectional views illustrating a peripheral region.

Referring to FIG. 2, an active region 12 and a device isolation film 14 defining the active region 12 are formed in a cell region and a peripheral region of a semiconductor substrate. Referring to the cross-sectional view of the Cell Y axis, a buried gate is formed in both of the active region 12 and the device isolation film 14. The buried gate is formed in a recess 22, which is formed to have a predetermined depth, in both the active region 12 and the device isolation film 14. The buried gate is formed by filling the recess 22 with a gate electrode 24 and a capping film 26. The capping film 26 preferably fills up the recess 22, and includes a nitride film.

In further detail, a hard mask pattern 28 for defining a region of the recess 22 is formed over the substrate 10 including the device isolation film 14 and the active region 12. The hard mask pattern 28 may include an oxide film, and the active region 12 and the device isolation film 14 are etched using the hard mask pattern 28 as a mask, thereby forming the recess 22 to a predetermined depth. A metal film such as tungsten (W), titanium (Ti), a titanium nitride film (TiN), or a conductive material such as polysilicon is deposited over the entire surface of the substrate 10, including the recess 22, and is then etched back, such that the conductive material remains only at a lower part of the recess 22, thereby forming the gate electrode 24. Thereafter, a nitride film having a predetermined thickness is deposited over the recess 22 and the hard mask pattern 28, such that the capping film 26 is formed.

Subsequently, hard mask layers 62 and 64 and a photoresist pattern 66 for forming the contact hole 32 are sequentially formed. The hard mask layer 62 and 64 may include an amorphous carbon layer or a silicon oxide nitride film, respectively. The capping film 26 and the active region 12 may be patterned using the photoresist pattern 66 and the hard mask layers 62 and 64 as a mask, such that the contact hole 32 is formed. Although a bit line contact hole will be used as an example of the contact hole 32 in the following description, the scope or spirit of the present invention is not limited thereto. The contact hole 32 may further include a landing plug contact hole or a storage node contact hole.

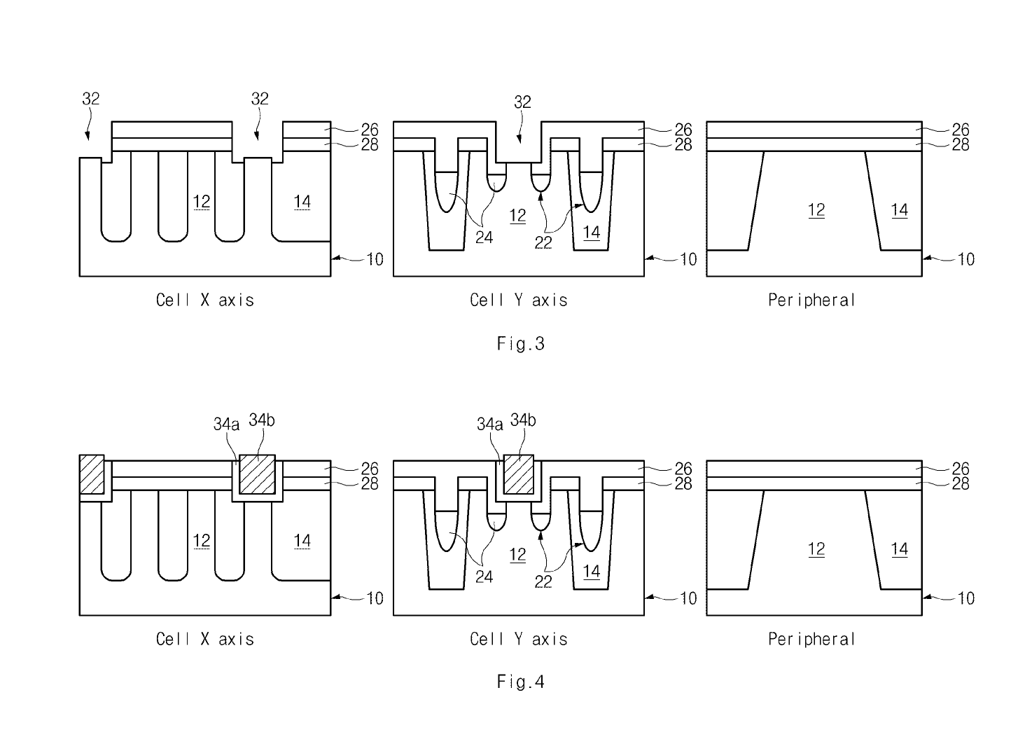

As can be seen from FIG. 3, the photoresist pattern 66 and the hard mask layers 62 and 64 are removed after the etching process by a cleaning process. Subsequently, as shown in FIG. 4, a thin conductive layer 34a is formed in a bottom region and at sidewalls of the contact hole 32. The conductive layer 34a preferably includes polysilicon. The conductive layer 34a may have a thickness of 400 nm to 500 nm. In the process of forming the conductive layer 34a, a thin polysilicon layer is deposited over the entire surface of the substrate 10 including the contact hole 32. The thin polysilicon layer is removed from the surface of the substrate 10 using an etch-back process such as an anisotropic etching process, but remains on the surface of the contact hole 32 forming the conductive layer 34a. Alternatively, a mask exposing the contact hole 32 may be formed over the capping film 26, and a thin polysilicon layer may be formed over the surface of the contact hole 32 through Atomic Layer Deposition (ALD).

Referring to FIG. 4, insulation film 34b is formed in the contact hole 32 in which the thin conductive layer 34a is formed. The insulation film 34b may include an oxide film. An oxide film having a predetermined thickness is deposited over the entire surface of the capping film 26 including the contact hole 32, and is then planarized by a Chemical Mechanical Polishing (CMP) process, thereby forming the insulation film 34b.

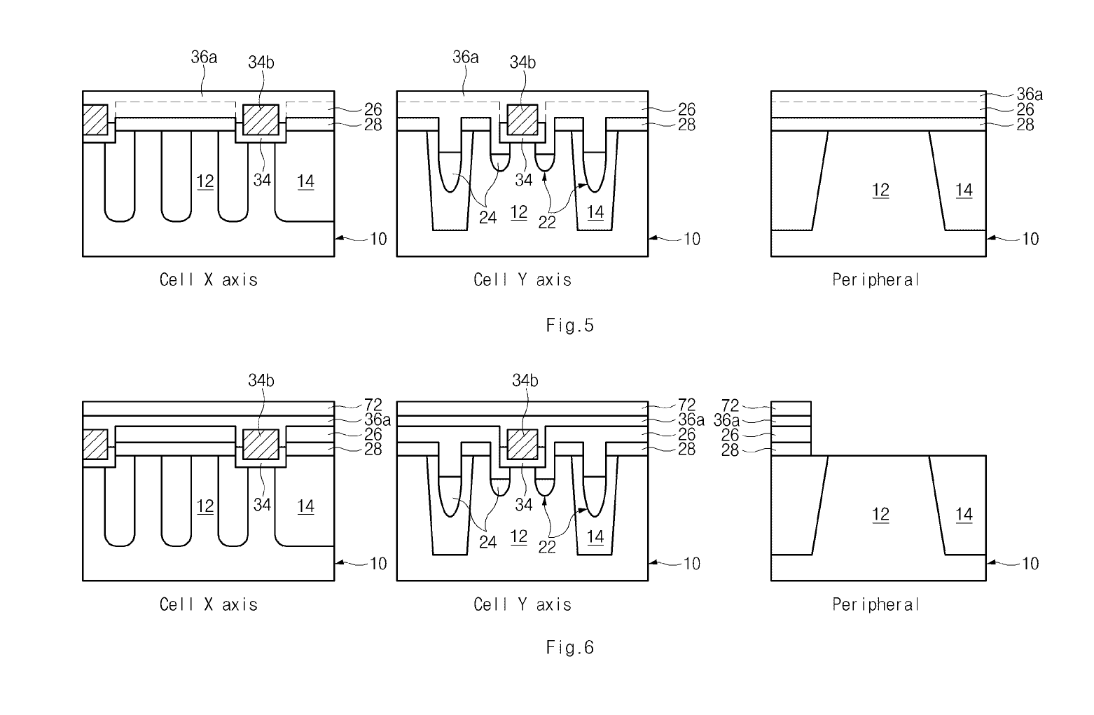

Referring to FIG. 5, the conductive layer 34a contained in the contact hole 32 is etched back to remove an upper part of the conductive layer 34a, thereby forming a first conductive layer 34. In this case, the process for etching back some parts of the conductive layer 34a may use etch selectivity between the polysilicon layer 34a and the oxide film 34b.

The width of the conductive layer 34a is preferably identical to that of the first conductive layer 34. In addition, through the above-mentioned process, the first conductive layer 34 may be configured in the form of an upstanding ‘U’ or a ‘U’ lying on its side. Subsequently, a nitride film 36a is formed over the entire surface of the capping film 26, including a region from which some parts of the conductive layer 34a have been removed, an upper part of the first conductive layer 34, and a lateral part of the insulation film 34b.

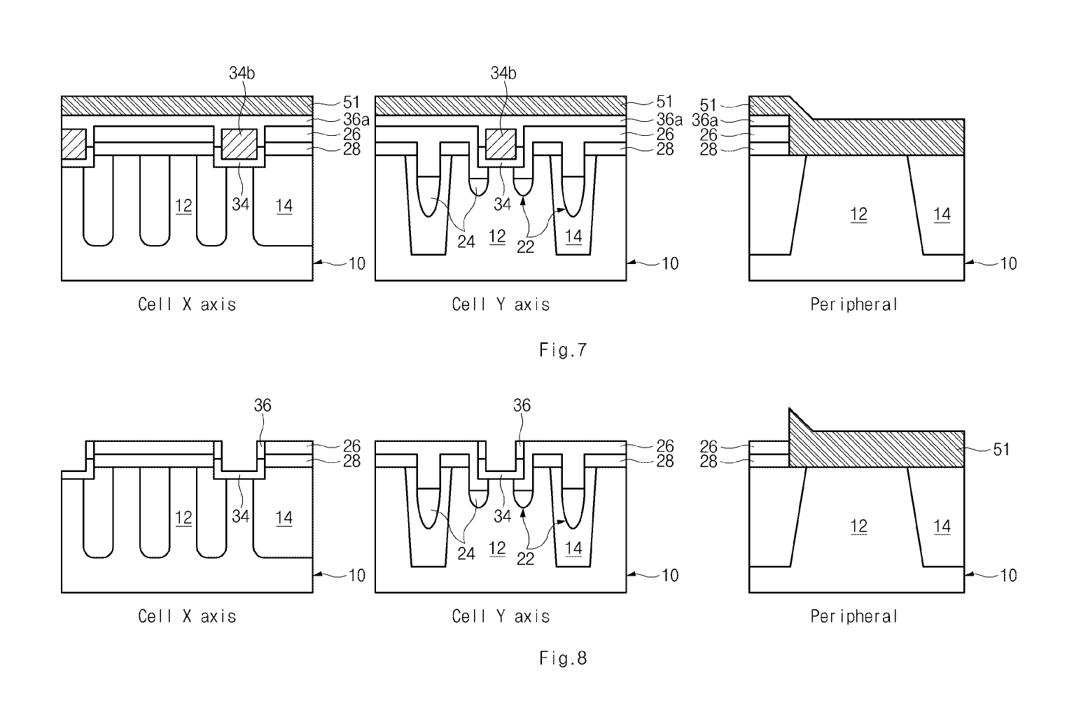

Referring to FIG. 6, a peripheral-circuit open mask 72 for opening a peripheral region is formed over the nitride film 36a, and the nitride film 36a and the capping film 26 of the peripheral region are etched using the peripheral-circuit open mask 72 as a mask. Then, the hard mask pattern 28 is removed from the peripheral region, such that the thickness of the remaining hard mask pattern 28 is reduced. Referring to FIG. 7, the peripheral-circuit open mask 72 is removed, an ion implantation process for the peripheral region and a process of forming a gate oxide film are carried out, and a polysilicon layer 51, having a predetermined thickness, is formed over the cell region and the peripheral region. The polysilicon layer 51 may be formed over a gate of the peripheral region.

Referring to FIG. 8, a cell open mask (not shown) for opening the cell region is formed, and the polysilicon layer 51 and the nitride layer 36a of the cell region are etched and removed, thereby forming a spacer 36. Subsequently, a cleaning process is performed in the cell region such that the insulation film 34b of the contact hole is also removed. As a result, a first conductive layer 34 is located at the bottom region of the contact hole 32 and the lower part of sidewalls of the contact hole 32, and the spacer 36 is located at the upper part of sidewalls of the contact hole 32.

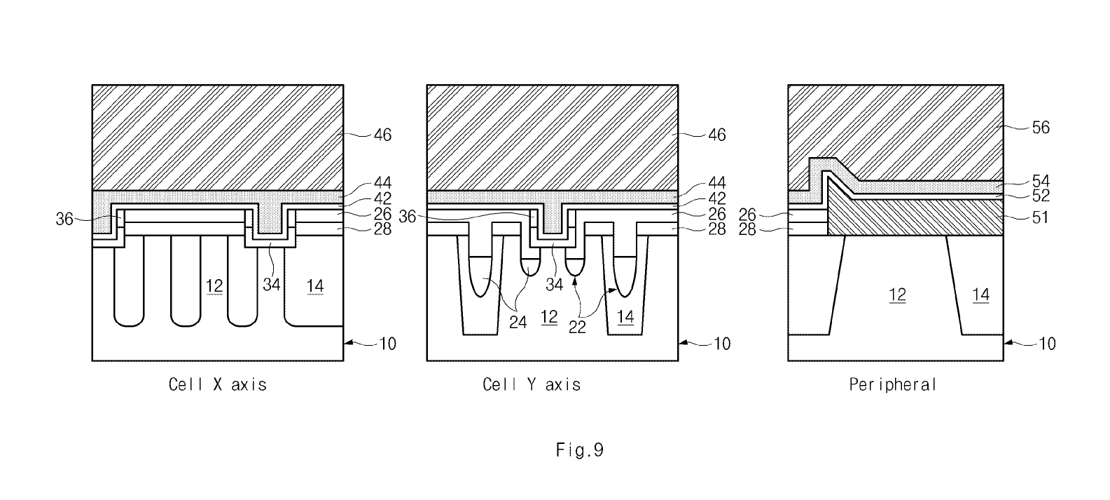

Referring to FIG. 9, barrier metal layers 42 and 52, conductive layers 44 and 54, and hard mask layers 46 and 56 are sequentially deposited over the entire surfaces of the cell region and the peripheral region. Preferably, the barrier metal layers 42 and 52 each may include a laminated structure of a titanium (Ti) film and a titanium nitride (TiN) film, the conductive layers 44 and 54 each may include tungsten (W), and the hard mask layers 46 and 45 each may include a nitride film. The barrier metal layers 42 and 52, the conductive layers 44 and 54, and the hard mask layers 46 and 56 form a bit line in the cell region and a gate in the peripheral region. Although it is preferable that the same materials be formed by the same process, the same materials may also be denoted by different reference numerals in the drawings for convenience of description and better understanding of the present invention.

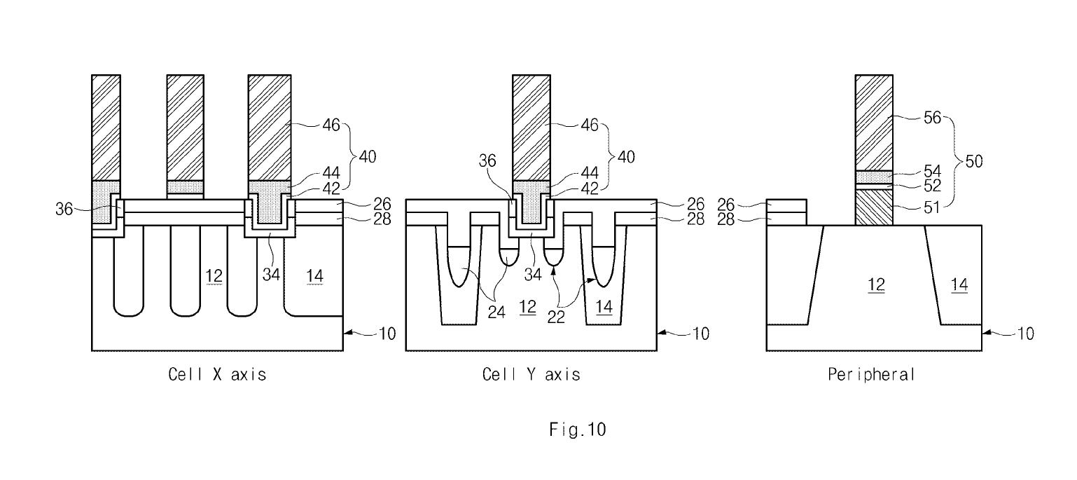

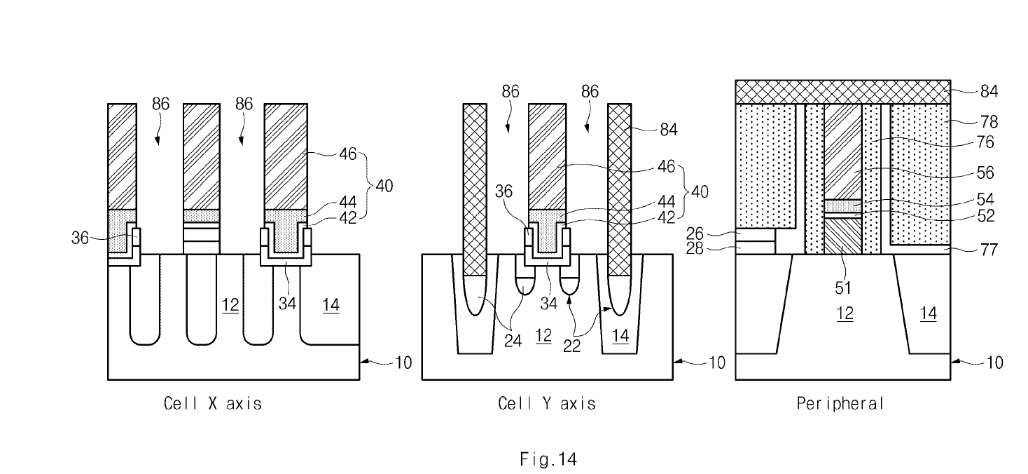

The contact hole 32 is filled with the barrier metal layer 42 and the conductive layer 44. In the following description, a stack of the barrier metal layer 42 and the conductive layer 44 in the contact hole 32 is referred to as a second conductive layer. The spacer 36, formed of a nitride material, is formed over an upper part of sidewalls, instead of the entirety of sidewalls, of the contact hole 32. Therefore, the size of the contact hole 32 where the second conductive layer is in contact with the substrate is not decreased, resulting in a reduction of resistance between the substrate and the second conductive layer. In addition, an etch-back process need not be used to form the spacer 36, and thus conventional problems caused by an etch-back process can be prevented. For example, short-circuit between the second conductive layer and a storage node contact plug, which is supposed to be formed in a storage node contact hole 86 as shown in FIG. 14, can be prevented. The second conductive layer may form a bit line contact plug or some parts of the bit line 40 (See FIG. 10).

Referring to FIG. 10, a photoresist pattern (not shown) is formed over the hard mask layers 46 and 56. The hard mask layers 46 and 56, the conductive layers 44 and 54, and the barrier metal layers 42 and 52 are etched using the hard mask layers 46 and 56 such that a cell bit line 40 and a peripheral circuit gate 50 are formed. The cell bit line 40 may be configured in the form of a laminated structure of the barrier metal layer 42, the bit line conductive layer 44 and the hard mask layer 46. The peripheral circuit gate 50 may be configured in the form of a laminated structure of the polysilicon layer 51, the barrier metal layer 52, the gate conductive layer 54 and the hard mask layer 56.

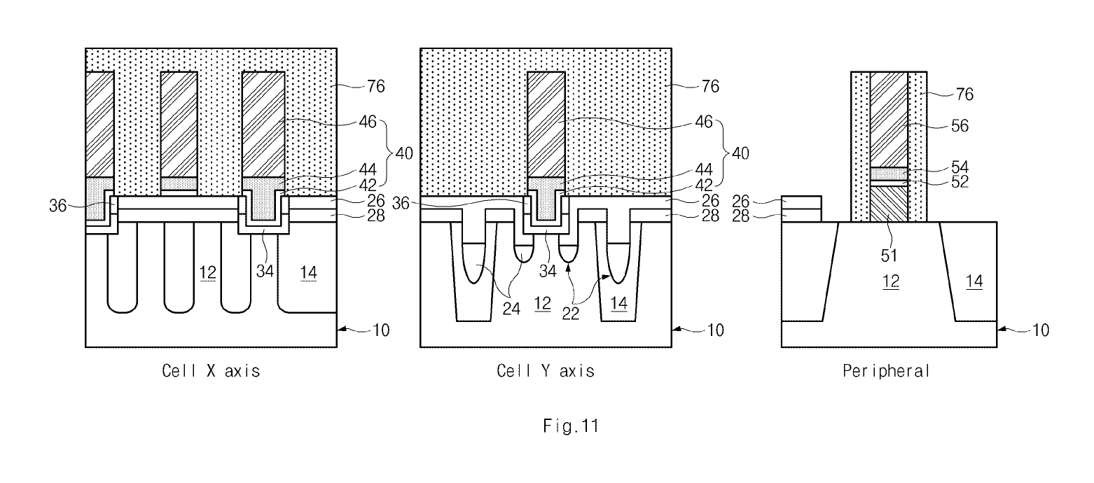

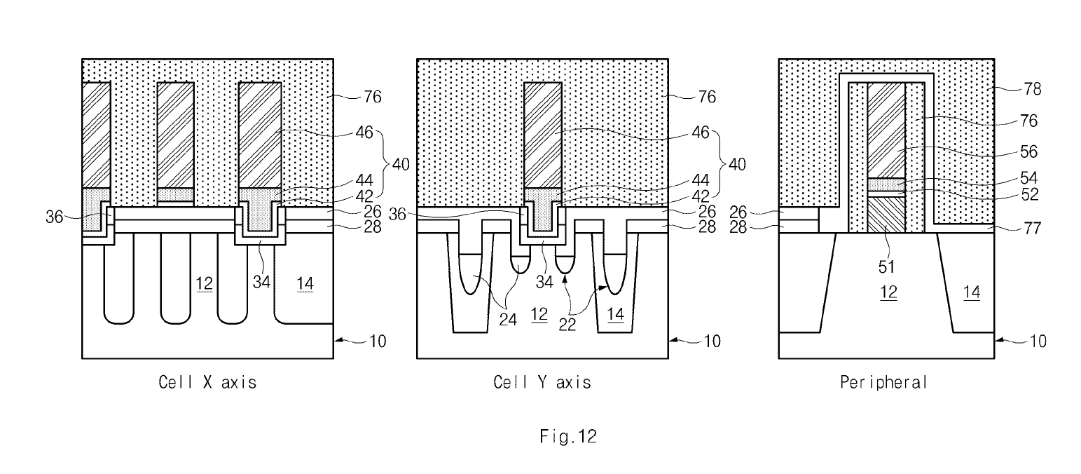

Referring to FIG. 11, an ion implantation insulation film 76 including an oxide film is deposited with a predetermined thickness over the entire surface of the substrate 10 including the cell bit line 40 and the peripheral circuit gate 50. The ion implantation insulation film 76 in the peripheral region is patterned to be a spacer-shaped ion implantation insulation film 76 at sidewalls of the peripheral circuit gate 50. Subsequently, the ion implantation process for the peripheral region is performed, and an additional spacer 77 formed of a nitride material is formed at sidewalls of the ion implantation insulation film 76 as shown in FIG. 12. An insulation film 78 is deposited over the peripheral region and the entire surface thereof is then planarized.

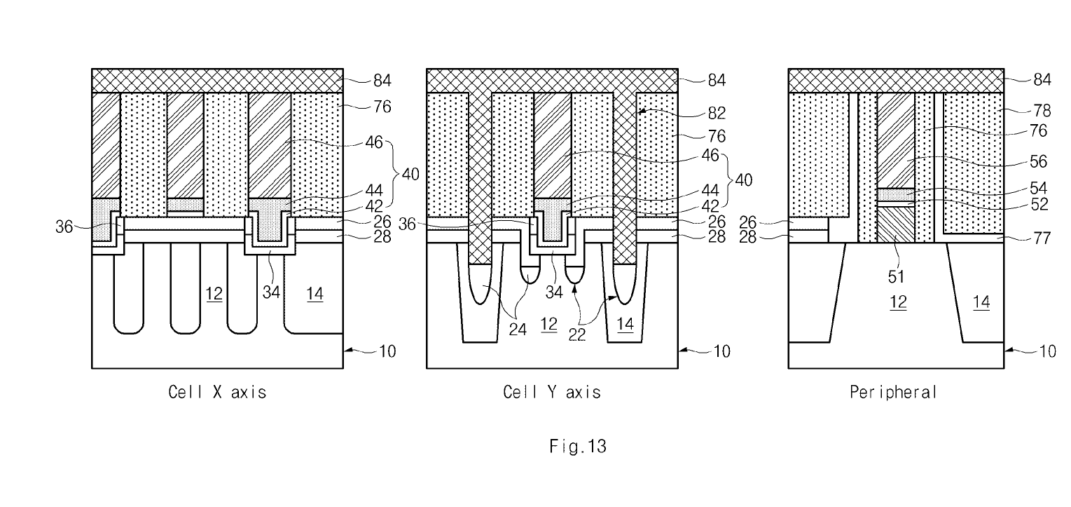

Referring to FIG. 13, a damascene recess 82 for forming a storage node in the cell region is formed, and a barrier layer 84 including a nitride film is formed over the entire surface including the damascene recess 82.

Referring to FIG. 14, the barrier film 84 formed over the insulation film 78 is planarized and etched by a chemical mechanical polishing (CMP) process. Subsequently, the storage node contact hole 86 for forming the storage node contact is formed. Although not shown in FIG. 14, a contact plug for burying the storage node contact hole 86 may be formed and then a storage unit (such as a capacitor) may be formed over the contact plug. In this case, the nitride spacer 36 having a sufficient thickness has already been formed at an upper part of the bit line contact hole 32. As a result, although the storage node contact hole 86 may be excessively etched, short circuit due to an excessively etched contact hole 86 is prevented.

As is apparent from the above description, the above-mentioned embodiments of the present invention provide a semiconductor device, and a method for forming the same, in which a contact hole spacer is formed over a contact hole sidewall in such a manner that a lower part of a contact plug is formed to have large width, thus reducing contact resistance is, and an upper spacer is not lost in a process of forming a contact hole sidewall spacer so as to prevent Self Align Contact (SAC) failure from occurring.

The above embodiments of the present invention are illustrative and not limitative. Various alternatives and equivalents are possible. The invention is not limited by the type of deposition, etching polishing, and patterning steps described herein. Nor is the present invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

The present invention includes the following:

In an embodiment, a semiconductor device includes a contact hole formed over a semiconductor substrate; a first conductive layer formed at a bottom region of the contact hole and a lower part of sidewalls of the contact hole; a spacer formed over the sidewalls of the contact hole; and a second conductive layer filling in the contact hole including the first conductive layer and the spacer.

In another embodiment, a method for forming a semiconductor device includes forming a contact hole over a semiconductor substrate; forming a first conductive layer at a bottom region of the contact hole and a lower part of sidewalls of the contact hole; forming a spacer over the sidewalls of the contact hole; and forming a second conductive layer in the contact hole including the first conductive layer and the spacer.

The formation of the first conductive layer further includes forming an insulation film over the first conductive layer; and etching upper parts of the first conductive layer. The insulation film includes any of SiO2, Boron Phosphorus Silicate Glass (BPSG), Phosphorus Silicate Glass (PSG), Tetra Ethye Ortho Silicate (TEOS), Un-doped Silicate Glass (USG), Spin On Glass (SOG), High Density Plasma (HDP), Spin On Dielectric (SOD), Plasma enhanced Tetra Ethyl Ortho Silicate (PE-TEOS), Silicon Rich Oxide (SROx), and a combination thereof. The formation of the spacer includes: depositing a spacer material over the etched first conductive layer; and etching/planarizing the spacer material.

The first conductive layer includes polysilicon; the spacer includes a nitride film; and the second conductive layer includes at least one of titanium (Ti), titanium nitride (TiN), or tungsten (W).

The method further includes, prior to the formation of the contact hole, forming a device isolation film defining an active region in the semiconductor substrate. A recess is formed in the semiconductor substrate. A buried gate is formed at a lower part of the recess. A capping film is formed over the buried gate and the semiconductor substrate. The contact hole is formed by etching the capping film.

In another embodiment, a method for forming a semiconductor device includes forming a contact hole over a semiconductor substrate; forming a first conductive layer at a bottom region of the contact hole and a lower part of sidewalls of the contact hole; forming a spacer over the sidewalls of the contact hole; and forming a second conductive layer in the contact hole including the first conductive layer and the spacer, wherein the first conductive layer is configured to have a shape of an upstanding ‘U’ or a ‘U’ lying on a side.

The first conductive layer formed at the lower part of sidewalls of the contact hole has a first width, wherein the first width of the first conductive layer is 0.9 to 1.1 times a second width of the spacer formed over the sidewalls of the contact hole. The first conductive layer is formed to have a thickness of 400 nm to 500 nm. The second conductive layer and gate conductive layer of a peripheral region is formed at the same time.

What is claimed is:

1. A semiconductor device comprising:
a contact hole formed over a semiconductor substrate;
a first conductive layer formed at a bottom region of the contact hole and a lower part of sidewalls of the contact hole;
a spacer formed over the sidewalls of the contact hole; and
a second conductive layer filling the contact hole including the first conductive layer and the spacer.

2. The semiconductor device according to claim 1, wherein the first conductive layer is configured to have a shape of an upstanding ‘U’ or a ‘U’ lying on a side.

3. The semiconductor device according to claim 1, wherein the first conductive layer formed at the lower part of sidewalls of the contact hole has a first width, wherein the first width of the first conductive layer is 0.9 to 1.1 times a second width of the spacer formed over the sidewalls of the contact hole.

4. The semiconductor device according to claim 1, wherein:
the first conductive layer includes polysilicon,
the spacer includes a nitride film, and
the second conductive layer includes any of titanium (Ti), titanium nitride (TiN), and tungsten (W).

5. The semiconductor device according to claim 1, further comprising a bit line formed over the second conductive layer.

6. The semiconductor device according to claim 1, wherein the first conductive layer is formed to have a thickness of 40 nm to 50 nm.

7. The semiconductor device according to claim 1, wherein the semiconductor substrate includes a cell region and a peripheral region, and
wherein a buried gate is buried in the cell region and a peripheral circuit gate is formed over the substrate of the peripheral region.

8. The semiconductor device according to claim 7, wherein the peripheral circuit gate has the same height as that of the second conductive layer of the cell region.

9. The semiconductor device according to claim 8, wherein:
the peripheral circuit gate includes a polysilicon layer, a barrier metal layer, a tungsten (W) layer, and a hard mask layer; and
a second conductive layer in the cell region includes a barrier metal layer, a tungsten layer, and a hard mask layer.

10. A semiconductor device comprising:
a buried cell gate in a cell region; and
a bit line plug formed in the cell region and coupled to the buried cell gate,
wherein the bit line plug is configured in a gourd-bottle shape having a narrow neck.

11. The semiconductor device of claim 10, the device further comprising an insulating layer formed over an outer surface of the bit line plug at the narrow neck.

12. The semiconductor device of claim 10, the device further comprising a planar peri gate in a peripheral region.

13. A semiconductor device comprising:
a buried cell gate in a cell region;
a first conductive pattern in U shape coupled to the buried cell gate;
an insulating pattern extending from an end of the conductive pattern along a first direction, wherein the first conductive pattern and the insulating pattern are integrated to form a first bit line plug in U shape; and
a second bit line plug filling in the first bit line plug to be coupled to the first conductive pattern and extending from the first bit line plug along the first direction.

14. The semiconductor device of claim 13, wherein the first conductive pattern has a first width at a bottom region and the second bit line plug has a second width between the insulating pattern, and
wherein the second width is smaller than the first width.

15. The semiconductor device of claim 14, the device further comprising a planar peri gate in a peripheral region,
wherein the planar peri gate is formed to substantially the same level as the second bit line plug.
